(19) United States
(12) Patent Application Publication
(10) Pub. No.: US 2002/0180479 A1
(43) Pub. Date: Dec. 5, 2002

(54) Pull-up terminator

(76) Inventor: Chi Chang, Taipei (TW)

Correspondence Address: Chien-Wei Chris Chou, Esq., OPPENHEIMER WOLFF & DONNELLY LLP, Suite 300, 101 Park Center Plaza, San Jose, CA, 95113, US

(21) Appl. No.: 09/975,118

(22) Filed: Oct. 10, 2001

(30) Foreign Application Priority Data
Jun. 4, 2001 (TW) 90113480

(51) Int. Cl. H03K 19/003

(52) U.S. Cl. 326/30

(57) ABSTRACT

The invention relates to a pull-up terminator formed using an N-type metal oxide semiconductor (NMOS) transistor connected in parallel to a P-type metal oxide semiconductor (PMOS) transistor, which achieves a constant resistance and effective termination using the higher control voltage on the gate electrode. The pull-up terminator using NMOS transistor includes: a PMOS transistor connected in parallel with an NMOS transistor, one end connected to a voltage source with the other end connected to an input/output terminal, the gate of the NMOS transistor connected to a control voltage and the substrate to the ground, the gate of the PMOS transistor connected to the control voltage with an inverted phase and the substrate to the voltage source. When the control voltage on the gate of the NMOS transistor is largely greater than the voltage source, using the NMOS transistor as a pull-up terminator can achieve effective termination.

### BACKGROUND OF THE INVENTION

1. Field of the Invention

The present invention relates to a pull-up termination resistor, especially to a pull-up terminator using an N-type metal oxide semiconductor (NMOS) transistor connected in parallel to a P-type metal oxide semiconductor (PMOS) transistor, which achieves a constant resistance and good termination effect using the higher control voltage on the gate electrode.

2. Description of Related Art

A typical terminator between the input/output terminals of two chips can be divided into an internal terminator and an external terminator. Typically, the external terminator is an external resistor. FIG. 1 is a typically external pull-up terminator. In the two chips, the input/output terminal 12 of the circuit 10 and the input/output terminal 22 of the circuit 20 are coupled by a transmission line 18 while a resistor 14 coupled to the terminal 12 and a resistor 24 coupled to the terminal 22 are respectively coupled to a voltage source (Vtt) by the free ends. The two resistors 14 and 24 are the external pull-up terminators.

Due to the external connection structure of the resistors 14 and 24, the manufacture of the circuit is costly as a result of the expense of purchasing the required resistors. Further, because the external resistor is not closed completely, DC power consumption is higher as the input/output terminals 12 and 22 output logic are low.

To overcome the above disadvantages, PMOS transistors are used in a chip at the position between the voltage source and the input/output terminal to form the internal pull-up terminator. FIG. 2 is a typically internal pull-up terminator. A PMOS transistor 34 is coupled between the input/output terminal 32 and the voltage source (Vtt) in the chip 30. A PMOS transistor 44 is coupled between the input/output terminal 42 and the voltage source (Vtt) in the chip 40. The two PMOS transistors 34 and 44 are the internal pull-up terminators.

The gates of the transistors 34 and 44 can dynamically activate the transistors 34 and 44, whether active or not, according to the control signal npu. This can solve the DC power consumption problem. FIG. 3 is a graph of voltage to current (V-I), where the voltage is the input/output terminal voltage as the gate voltage of the PMOS transistor is grounded, and the current is the current passing through the PMOS transistor. In the graph, the voltage of the input/output terminal from 0V to about 1V is in the saturation state such that the equivalent resistance of the PMOS transistor is higher. This causes a problem, in that the PMOS transistor cannot keep an input signal level as usual with insufficient pull-up current because the input signal on the input/output terminal is reduced. Hence, the input signal level becomes undershot so that the ring-back signal becomes very high. When the ring-back signal is over an internal reference voltage V_{REF}, error data is incurred.

FIG. 4 is a graph illustrating the relationship between the input/output terminal voltage and the time as a linear resistance (LR) and a non-linear resistance (NLR) for a pull-up terminator. The pull-up current is unstable because the equivalent circuit of the PMOS transistor is non-linear. As shown in the figure, when a linear resistance (LR) is applied and provides a more stable pull-up current to the terminator, the input signal is not undershot and the ring-back signal is reduced. Therefore, the termination effect provided by the linear resistance (LR) for a terminator is preferred.

### SUMMARY OF THE INVENTION

Accordingly, an object of the invention is to provide a pull-up terminator, which uses a N-type metal oxide semiconductor (NMOS) transistor connected in parallel to a P-type metal oxide semiconductor (PMOS) transistor, thereby achieving a constant resistance value and good termination effect.

Another object of the invention is to provide a pull-up terminator, which only uses a NMOS transistor as the pull-up terminator when the control voltage connected to the gate of the NMOS transistor is higher than the voltage source, thereby achieving a constant resistance value and good termination effect.

The invention provides a pull-up terminator, coupled between the voltage source and the input/output terminal and operated by the control voltage. The pull-up terminator includes: the source and substrate of a PMOS transistor coupled to a voltage source, the drain coupled to the input/output terminal, the gate operating at the PMOS transistor according to a control voltage after phase inversion; and the drain of an NMOS transistor coupled to the voltage source, the substrate coupled to ground, the source coupled to the input/output terminal, the gate operating at the NMOS transistor according to the control voltage.

The pull-up terminator also includes: a first inverter connected in series to a second inverter, the source and substrate of a PMOS transistor coupled to a voltage source, the drain coupled to the input/output terminal, the gate coupled to the output of the second inverter; and the drain of an NMOS transistor coupled to the voltage source, the substrate coupled to ground, the source coupled to the input/output terminal, the gate coupled to the output of the first inverter.

The invention provides a pull-up terminator coupled between the voltage source and the input/output terminal, including: the drain of an NMOS transistor coupled to the voltage source, the substrate coupled to ground, the source coupled to the input/output terminal; and a control voltage coupled to the gate of the NMOS transistor and greater than the voltage source.

### BRIEF DESCRIPTION OF THE DRAWINGS

The invention will become apparent by referring to the following detailed description of a preferred embodiment with reference to the accompanying drawings, wherein:

FIG. 1 is a schematic diagram illustrating a typically external pull-up terminator;

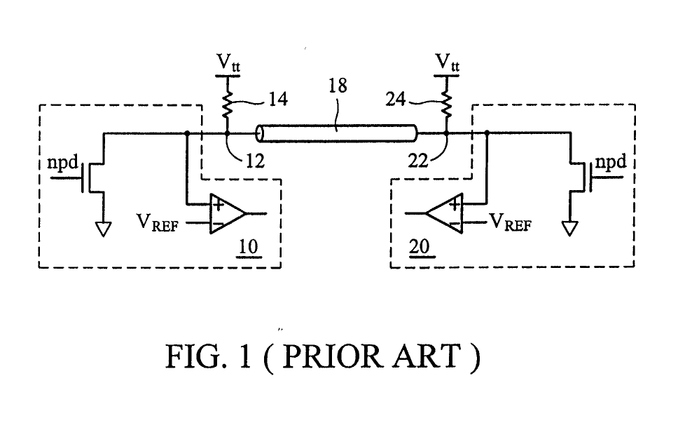

FIG. 2 is a schematic diagram illustrating a typically internal pull-up terminator;

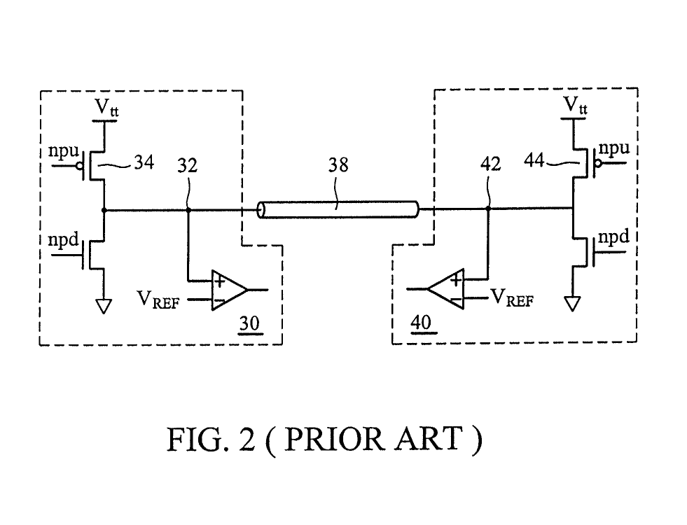

FIG. 3 is a graph of the voltage-to-current ratio of the input/output terminal of a PMOS;

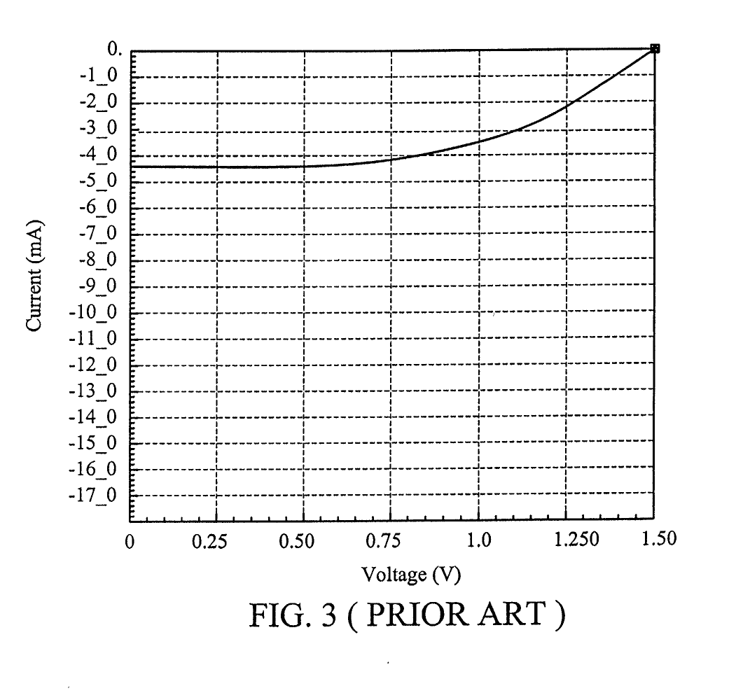

FIG. 4 is a graph illustrating the relationship between the input/output terminal voltage and the time as a linear resistance and a non-linear resistance for a pull-up terminator;

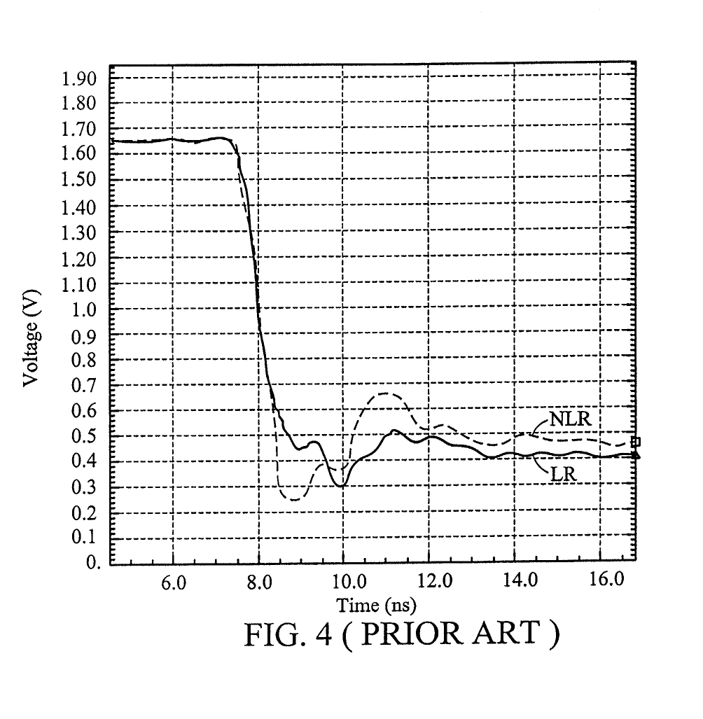

FIG. 5 is a schematic diagram illustrating a pull-up terminator of the invention using an NMOS transistor connected in parallel to a PMOS transistor;

FIG. 6 is a graph of the input/output terminal voltage to the current passing through the PMOS and the NMOS, respectively;

FIG. 7 is a graph of the resistance for input/output terminal voltage respectively with respect to the PMOS transistor, the NMOS transistor and the equivalent resistance as the PMOS transistor is connected in parallel to the NMOS transistor;

FIG. 8 is an embodiment of the pull-up terminator of the invention with a transmission line;

FIG. 9 is a graph of the equivalent resistance for the input/output terminal voltage to the NMOS transistor when the control voltage (Vdd) on the gate of the NMOS transistor operated at 3.3V and 2.5V; and

FIG. 10 is another embodiment of the pull-up terminator of the invention with a transmission line.

### DETAILED DESCRIPTION OF THE INVENTION

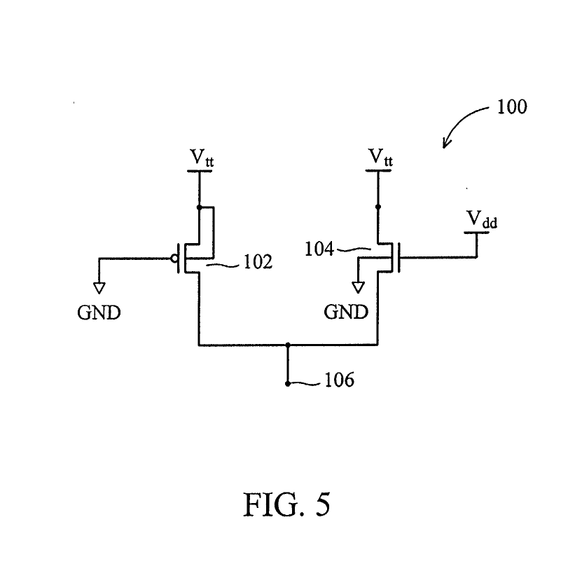

FIG. 5 is a schematic diagram illustrating a pull-up terminator of the invention using an NMOS transistor connected in parallel to a PMOS transistor. In FIG. 5, the pull-up terminator includes: a PMOS transistor 102 connected in parallel to an NMOS transistor 104, wherein the source and substrate of the PMOS transistor are connected to the voltage source (Vtt=1.5V) while the gate is connected to ground (Gnd), and the drain is connected to the input/output terminal 106. Further, the drain of the NMOS transistor is connected to the voltage source (Vtt) while the gate is connected to the control voltage (Vdd), the substrate is connected to ground (Gnd) and the source is connected to the input/output terminal 106.

This pull-up terminator is simulated on the basis of the typical 0.22 micrometer corner process of the Taiwan Semiconductor Manufacturing Company, Ltd. (TSMC). The simulated PMOS transistor is of the width Wp and the channel length Lp of 125 micrometers and 0.5 micrometers, while the simulated NMOS transistor is of the width Wn and the channel length Ln of 50 micrometers and 0.5 micrometers.

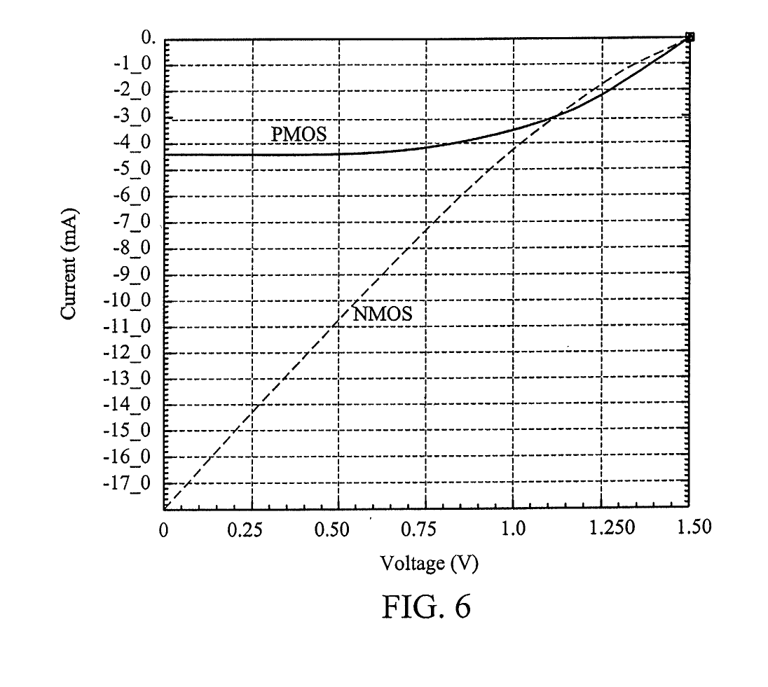

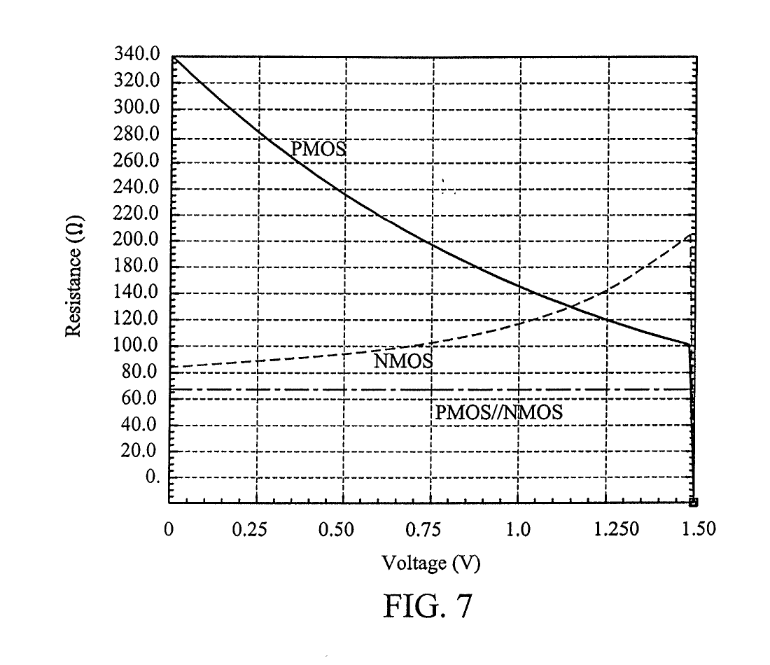

FIG. 6 is a graph of the input/output terminal voltage to the current passing through the PMOS and the NMOS, respectively. In this example, the control voltage (Vdd) on the gate of the NMOS transistor is operated at 2.5V. FIG. 7 is a graph of the input/output terminal voltage respectively with respect to the PMOS transistor, the NMOS transistor and the equivalent resistance under this condition of FIG. 6.

As illustrated in FIGS. 6 and 7, when the PMOS transistor is satisfied by the condition of |_{GSP}| |V tp0|, the current passing through the PMOS transistor enters the saturation state, wherein V_{GSP} represents the potential difference between the gate and source of the PMOS transistor, and Vtp0 is the threshold voltage of the PMOS transistor without body effect. This means that the curve rises steeply at the point of V_{GSP} less than the threshold value Vtp0. Thus the pullup terminator is not enough to maintain a normally input signal level, which is a problem of typical pull-up terminators.

Accordingly, the shunt NMOS device of the invention can solve the problem seen in the prior art. When the input/output terminal voltage drops, the gate of the NMOS transistor is connected to the control voltage (Vdd=2.5V), and the initial voltages of the source and drain of the NMOS transistor are kept at 1.5V. Under these conditions, it is assumed that when the body effect Vsb of the NMOS transistor is 1.5V, the threshold voltage (Vtn) of the NMOS transistor is higher than Vtn0, the threshold value without body effect. However, even if V_{GSN}=2.5-1.5=1V is still higher than Vtn at the gate voltage V_{G}=2.5V, the current increase follows on the increasing voltage difference V_{GSN}−Vtn as the input/output terminal voltage is decreased. The linear resistance of the NMOS better than that of the PMOS is created. That is, when the input/output terminal voltage is lower than 0.75V, the equivalent resistance of the NMOS transistor is maintained at the range less than the resistance range of the PMOS transistor, and provides sufficient current as compared to the PMOS when the input/output terminal voltage is lower than 0.7V. Different resistance curves can be created by adjusting Wn of the NMOS transistor and Wp of the PMOS transistor. As simulated in FIG. 7, according to the embodiment, the preferred linear resistance is formed by adjusting Wp/Wn=2.5. The input/output terminal voltage ranging between 0 and 1.5V can create a linear resistance. The equivalence of the linear resistance is about 68. The linear resistance can be changed easily by adjusting the values Wp and Wn, thereby reducing interference in a transmission line because of the ringback signal.

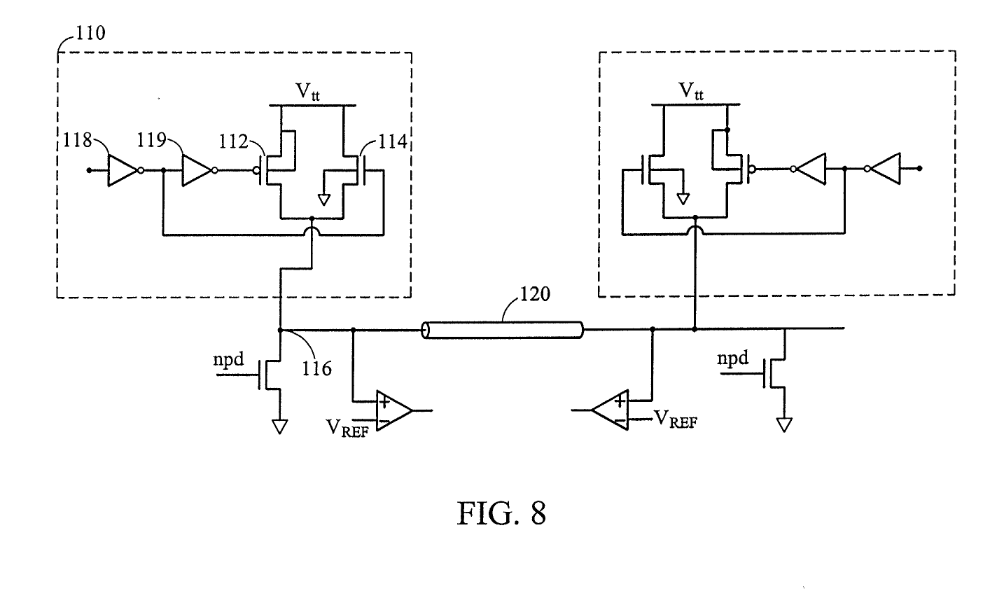

FIG. 8 is an embodiment of the pull-up terminator of the invention with a transmission line. The pull-up terminator 110 connected to a transmission line 120 includes a PMOS transistor 112, an NMOS transistor 114, a first inverter 118, and a second inverter 119, wherein the source and substrate of the PMOS transistor are connected to the voltage source (Vtt) and the drain is connected to the input/output terminal 116. The drain of the NMOS transistor 114 is connected to the voltage source (Vtt), the substrate connected to ground (Gnd), and source connected to the input/output terminal 106. The invention also provides two inverters 118 and 119 operating at the control voltage of Vdd (2.5V). The output of the first inverter 118 is connected to the input of the second inverter 119 and the gate of the NMOS transistor 114 while the output of the second inverter 119 is connected to the gate of the PMOS transistor. When the input of the first inverter 118 receives a high logic level signal, the gate of the PMOS transistor 112 receives a low logic level signal to turn on the PMOS transistor 112. The gate of the NMOS transistor 114 receives a high logic level signal (i.e. a control voltage Vdd=2.5V) to turn on the NMOS transistor 114, thereby having a constant equivalent resistance value. When the input of the first inverter 118 receives a low logic level signal, the PMOS transistor 112 and the NMOS transistor 114 are turned off concurrently.

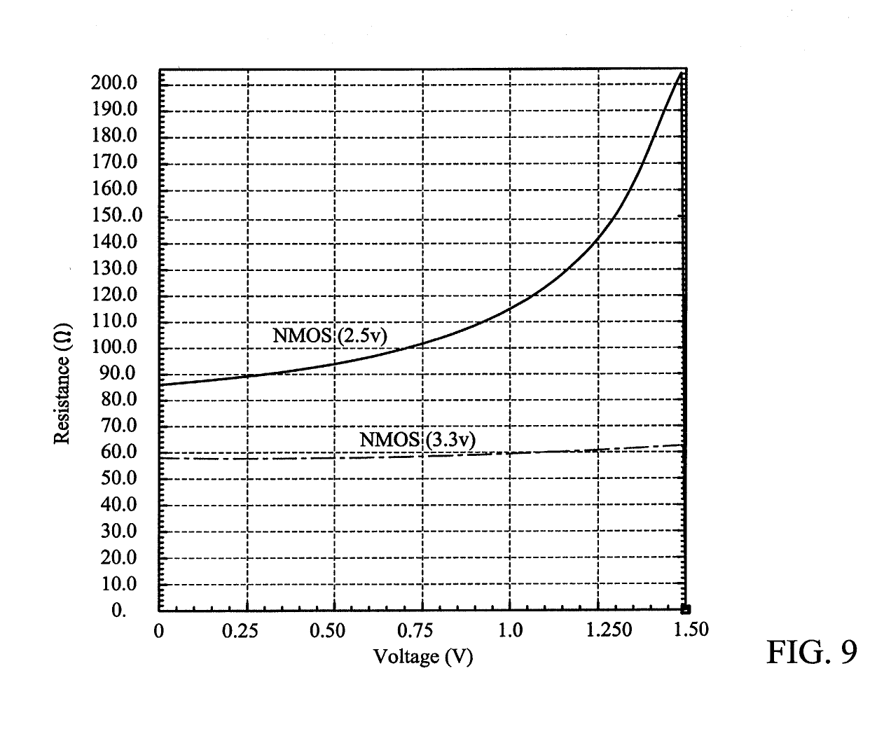

FIG. 9 is a graph of the equivalent resistance for the input/output terminal voltage to the NMOS transistor when the control voltage (Vdd) on the gate of the NMOS transistor operates at 3.3V and 2.5V. As shown in FIG. 9, because the control voltage of the NMOS transistor at 3.3V is largely greater than the voltage source (according to the embodiment, it is regarded that the control voltage is largely greater than the voltage source when the control voltage is 1.5V or more greater than the voltage source). At this point, the NMOS transistor is completely operated in a linear region such that the NMOS transistor having a linear resistance feature, no need of implementing the PMOS transistor, can be implemented as a pull-up terminator. When the control voltage (Vdd) of the NMOS transistor is operated at 2.5V, the NMOS transistor connected in parallel to the PMOS transistor is implemented as the pull-up terminator having a linear resistance feature.

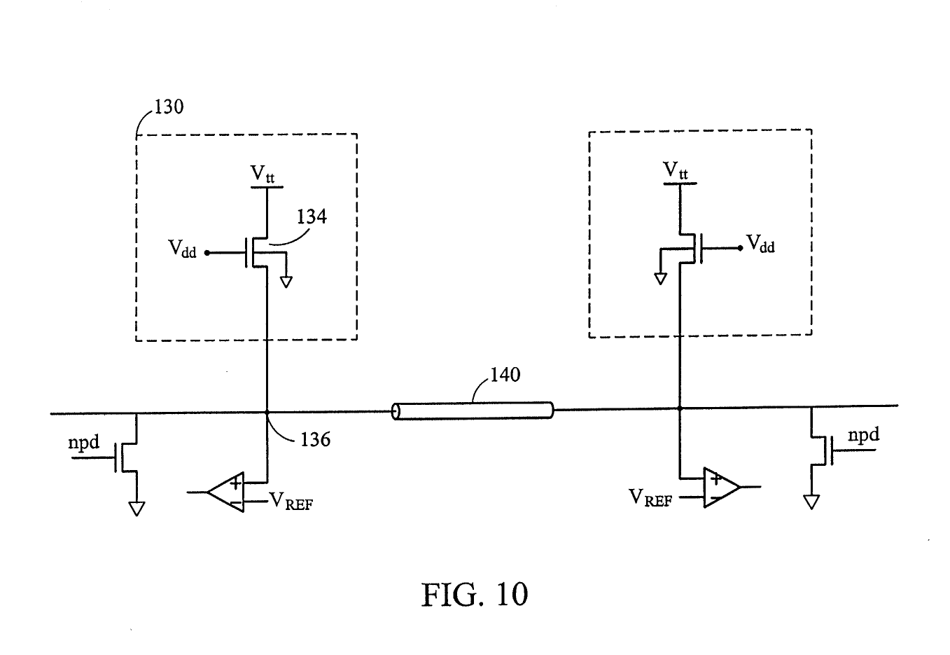

FIG. 10 is another embodiment of the pull-up terminator of the invention with a transmission line. The pull-up terminator 130 connected to a transmission line 140 includes an NMOS transistor 134, wherein the drain of the NMOS transistor 134 is connected to the voltage source (Vtt), the substrate to ground (Gnd), the source to the input/output terminal 136. The control voltage received from the gate is largely greater than the voltage source, e.g. 3.3V.

Therefore, when the control voltage (3.3V) is input to the gate of the NMOS transistor 134, the pull-up terminator 130 has a constant equivalent resistance. The pull-up terminator 130 is turned off when the control voltage is input to the NMOS transistor 134.

Accordingly, the advantage of the invention is to provide a pullup terminator, wherein an NMOS transistor is connected in parallel to a PMOS transistor, such that the pull-up terminator has a constant resistance to achieve effective termination.

Another advantage of the invention is to provide a pull-up terminator, wherein when the control voltage connected to the gate of an NMOS transistor is largely greater than the voltage source, the pullup terminator having a constant resistance only uses the NMOS transistor to achieve effective termination.

Although the present invention has been described in its preferred embodiment, it is not intended to limit the invention to the precise embodiment disclosed herein. Those who are skilled in this technology can still make various alterations and modifications without departing from the scope and spirit of this invention. Therefore, the scope of the present invention shall be defined and protected by the following claims and their equivalents.

What is claimed is:

1. A pull-up terminator, coupled between a voltage source and an input/output terminal, the pull-up terminator comprising:
a PMOS transistor, having a source and a substrate coupled to the voltage source, a drain coupled to the input/output terminal, and a gate operating the PMOS transistor according to a control voltage with an inverted phase; and
an NMOS transistor, having a drain coupled to the voltage source, a substrate coupled to a ground voltage, a drain coupled to the input/output terminal, and a gate operating the NMOS transistor according to the control voltage.

2. The pull-up terminator of claim 1, wherein the voltage source is a direct voltage source.

3. The pull-up terminator of claim 1, wherein a ratio of the PMOS transistor's width with respect to the NMOS transistor's width is a constant value.

4. The pull-up terminator of claim 3, wherein the constant value is about 2.5

5. The pull-up terminator of claim 1, wherein a length of the PMOS is the same as a length of the NMOS.

6. The pull-up terminator of claim 1, wherein the control voltage is greater than the voltage source.

7. A pull-up terminator, coupled between a voltage source and an input/output terminal, the pull-up terminator comprising:
a first inverter for operating in a control voltage;
a second inverter connected in series with the first inverter for operating in the control voltage;
a PMOS transistor, having a source and a substrate coupled to the voltage source, a drain coupled to the input/output terminal, and a gate coupled to an output of the second inverter; and
an NMOS transistor, having a drain coupled to the voltage source, a substrate coupled to a ground voltage, a drain coupled to the input/output terminal, and a gate coupled to an output of the first inverter.

8. The pull-up terminator of claim 7, wherein the control voltage is greater than the voltage source.

9. The pull-up terminator of claim 7, wherein the voltage source is a direct voltage source.

10. The pull-up terminator of claim 7, wherein a ratio of the PMOS transistor's width with respect to the NMOS transistor's width is a constant value.

11. The pull-up terminator of claim 10, wherein the constant value is 2.5

12. The pull-up terminator of claim 7, wherein a length of the PMOS is the same as a length of the NMOS.

13. A pull-up terminator, which coupled between a voltage source and an input/output terminal, the pull-up terminator comprising:
an NMOS transistor, having a drain coupled to the voltage source, a substrate coupled to a ground voltage, a drain coupled to the input/output terminal; and
a control voltage coupled to a gate of the NMOS transistor and the control voltage greater than the voltage source.

14. The pull-up terminator of claim 13, wherein the control voltage is at least 1.5V greater than the voltage source.
